(19) United States
(12) Patent Application Publication
(10) Pub. No.: US 2008/0213622 A1
(43) Pub. Date: Sep. 4, 2008

(54) Organic electroluminescence element

(75) Inventor: Masanori Maeda, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto-shi (JP)

(21) Appl. No.: 11/974,910

(22) Filed: Oct. 16, 2007

(30) Foreign Application Priority Data
Oct. 16, 2006 (JP) 2006-281678

(51) Int. Cl. H05B 33/14

(52) U.S. Cl. 428/690

(57) ABSTRACT

Provided is an organic EL element in which an anode, a hole injection layer, a hole transport layer, an emissive layer, an electron transport layer, an electron injection layer, and a cathode are stacked up on top of a substrate. Into at least one of the organic layer—the hole injection layer and the hole transport layer, an organic material different from the organic material constituting the corresponding one of the organic layers is doped. The doped organic material contributes to the formation of an impurity level to trap the holes. Consequently, the mobility of the holes can be lowered.

### CROSS REFERENCE TO RELATED APPLICATIONS AND INCORPORATION BY REFERENCE

This application is based upon and claims the benefit of prior Japanese Patent Application P2006-281678 filed on Oct. 16, 2006; the entire contents of which are incorporated by reference herein.

### BACKGROUND OF THE INVENTION

1. Field of the Invention

The present invention relates to an organic electroluminescence element (an organic EL element) that has a longer service life as a device.

2. Description of the Related Art

In a conventional-type organic EL element, organic layers are formed so as to sandwich an emissive layer. The organic layers facilitate the carries, such as electrons and holes, to be injected into the emissive layer. In addition, an electrode is formed at the outer side of each of the organic layers.

FIG. 5 shows an example of the structure of an organic EL element. In the structure, an anode 22, a hole injection layer 23, a hole transport layer 24, an emissive layer 25, an electron transport layer 26, a cathode 27 are stacked up in this order on top of a glass substrate 21. The anode 22 is formed of a transparent electrode, and the light emitted from the emissive layer 25 is taken out in a direction indicated by the arrow in FIG. 5.

The electron transport layer 26 is used for making the electrons transfer smoothly to the emissive layer 25, and for preventing the holes that have entered the emissive layer 25 from moving into the electron transport layer 26. In contrast, the hole transport layer 24 is used for making the holes transfer smoothly to the emissive layer 25, and for preventing the electrons that have entered the emissive layer 25 from moving into the hole transport layer 24.

In addition, the hole injection layer 23 is provided for facilitating the injection of the holes into the emissive layer 25 by lowering the energy barrier that exists between the emissive layer 25 and the anode 22. The layers of the organic EL element shown in FIG. 5 are individually formed by the vacuum deposition method.

In the conventional-type organic EL element, however, there is always an accumulation of holes at the interface between the hole transport layer 24 and the emissive layer 25. To put it other way, the interface is in a hole-rich state for the current.

The energy diagram of FIG. 4 shows this hole-rich state for the current. Holes are injected from the anode 22 while electrons are injected from the cathode 27. As shown in FIG. 4, an energy barrier exists at the interface between two adjacent layers. Both the holes and the electrons can move towards the emissive layer 25 while surmounting the respective energy barriers.

As described in Yuki EL Disupurei (Organic EL Display), Ohmsha Ltd., published on Aug. 20, 2004, pp. 61-63, the hole mobility of the hole transporting material used for the hole injection layer 23 and the hole transport layer 24 is larger than the electron mobility of the electron transporting material used for the electron transport layer 26, normally, by approximately double digits. Accordingly, the holes reach the emissive layer 25 faster than the electrons. One of the reasons for this is because the electrons moving within the electron transporting material are more likely to be trapped than the holes moving within the hole transporting material.

As has described above, fewer electrons can reach the emissive layer 25 than the holes, so that the balance between the numbers of electrons and that of holes is lost within the emissive layer 25. A number of holes that cannot find electrons to be recombined with accumulate at the interface between the hole transport layer 24 and the emissive layer 25. The accumulated holes continuously oxidize organic molecules within the emissive layer 25, and the emissive layer 25 stays in a radial-cation state for a longer time. Hence the organic molecules in the emissive layer 25 tend to be degraded. Such degradation, in turn, shortens the service life of the device.

The present invention is made to address the above-described problems, and aims to provide an organic EL element capable of preventing the emissive layer from degrading and of having a longer service life as a device.

### SUMMARY OF THE INVENTION

A first aspect of the present invention provides an organic EL element that includes any one of a hole injection layer and a hole transport layer provided between an emissive layer and an anode. In the organic EL element, at least any one of the hole injection layer and the hole transport layer is doped with an organic material that is different from an organic material constituting the corresponding one of the organic layers.

A second aspect of the present invention provides an organic EL element according to the first aspect, in which element the doped organic material is the same fluorescent material that is used for the emissive layer.

According to the present invention, a hole trap can be intentionally created in the hole injection layer or in the hole transport layer by doping an organic material that is different from the organic material constituting the organic layer—the hole injection layer or hole transport layer. With these effects, the hole mobility in the hole injection layer and the hole mobility in the hole transport layer can be lowered, so that the holes and the electrons in the emissive layer can be balanced. As a consequence, the amount of holes accumulated at the interface between the hole transport layer and the emissive layer can be reduced, and thus the degradation of the emissive layer can be suppressed.

### BRIEF DESCRIPTION OF DRAWINGS

FIG. 1 illustrates a sectional structure and a material configuration for an organic EL element according to the present invention.

FIG. 2 illustrates an energy diagram of a hole transport layer doped with a dopant B.

FIG. 3 illustrates a measurement data of comparing a conventional-type organic EL element and an organic EL element doped with an organic material into a hole injection layer or into a hole transport layer.

FIG. 4 illustrates an energy diagram of a conventional-type organic EL element.

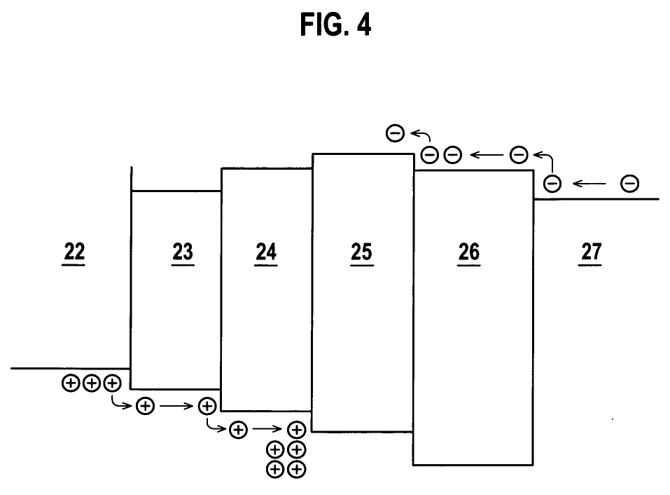

FIG. 5 illustrates a sectional structure of a conventional-type organic EL element.

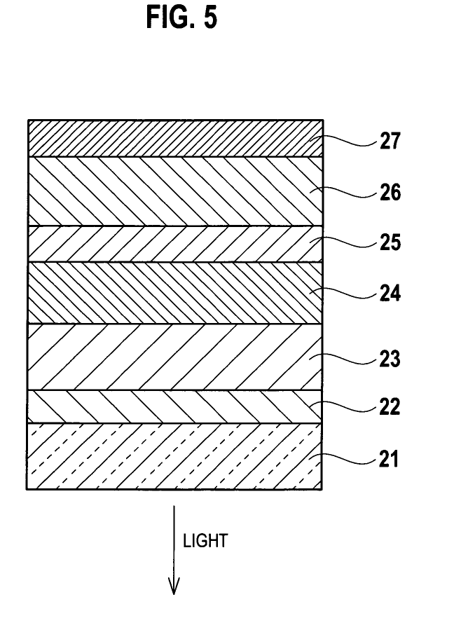

### DETAILED DESCRIPTION OF THE INVENTION

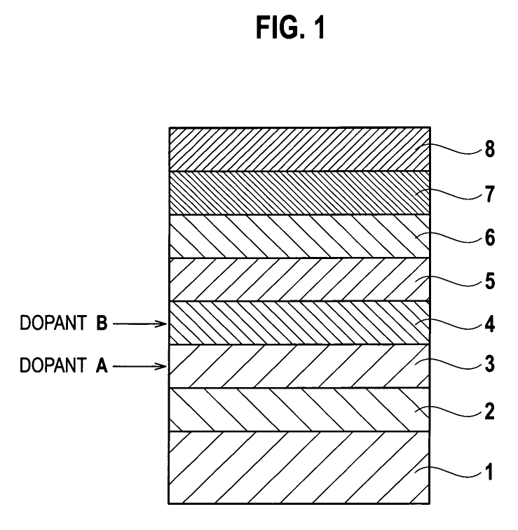

An embodiment of the present invention will be described with reference to the accompanying drawings. FIG. 1 illustrates the structure of an organic EL element according to the present invention. An anode 2, a hole injection layer 3, a hole transport layer 4, an emissive layer 5, an electron transport layer 6, an electron injection layer 7, and a cathode 8 are stacked up on top of a substrate 1.

The emissive layer 5 is formed, for example, by doping a fluorescent dye into a luminescence material (host material) so as to emit light of a particular color within the visible light range (400 nm to 750 nm). For example, to emit green light, an organic material obtained by doping coumarin C545T or quinacridone into an aluminum-quinolinol complex, and the like is used as a material for the emissive layer 5.

The electron transport layer 6 is made of an aluminum-quinolinol complex, oxadiazoles, or the like while the electron injection layer 7 is made of a lithium complex, an alkali metal, such as lithium, or the like. The cathode 8 is made of a metal, such as aluminum. The hole transport layer 4 is made of naphthyl-phenyl benzidine (NPB), a triphenylamine derivative (TPD), NPD, or the like. The hole injection layer 3 is made of phthalocyanines, an oligoamine compound, or the like. A transparent substrate made of, for example, glass is used as the substrate 1 while a transparent electrode of, for example, ITO is used as the anode 2.

According to the present invention, an organic material is doped into at least one of the organic layers, to be more specific, the hole injection layer 3 and the hole transport layer 4. Here, the doped organic material is different from the organic materials constituting the respective organic layers 3 and 4. This is what characterizes the present invention. In this embodiment, while an organic material A is doped into the hole injection layer 3, an organic material B is doped into the hole transport layer 4.

An element for comparison used in this embodiment had the following basic structure. A substrate 1 was made of a glass substrate; an anode 2 was made of ITO; a hole injection layer 3 was made of an oligoamine compound; a hole transport layer 4 was made of NPB (naphthyl-phenyl benzidine); an emissive layer 5 was made of an organic material formed by doping, into a distyrylarylene compound as a host material, a styryl amine compound as a fluorescent material and as a guest material; an electron transport layer 6 was made of an aluminum-quinolinol complex (Alq₃); an electron injection layer 7 was made of lithium fluoride (LiF); and a cathode 8 was made of aluminum (Al). These layers of the organic EL element were individually formed by the vacuum deposition method.

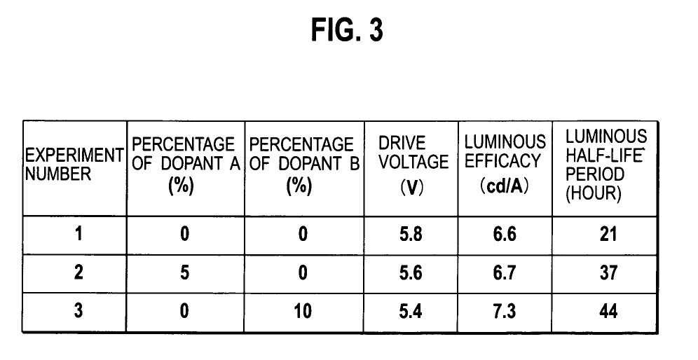

Two types of organic EL elements according to the present invention were fabricated. One of the two elements had an element structure in which only the hole injection layer 3 of the element for comparison had an organic material A (dopant A) doped thereinto. The other one of the two elements had an element structure in which only the hole transport layer 4 had an organic material B (dopant B) doped thereinto. FIG. 3 shows the results of comparison between these two elements and the element for comparison.

Experiment number 1 in FIG. 3 represents the element for comparison, which had a structure with the un-doped hole injection layer 3 and the un-doped hole transport layer 4. Experiment number 2 represents the element in which only the hole injection layer 3 was doped with the organic material A while experiment number 3 represents the element in which only the hole transport layer 4 was doped with the organic material B.

Then, the drive voltage, the luminous efficacy, and the luminous half-life period for each element were measured. The luminous half-life period mentioned here means the period of time that it takes for an element made to emit light continuously to have half the luminance of the luminance at the beginning. As a condition for the testing of the luminous half-life period, the initial luminance of the measurement was set at 10000 cd/m². In addition, the drive voltage and the luminous efficacy were adjusted so that the element could be driven to have the 1000-cd/m² initial luminance.

Meanwhile, the element of experiment number 2 was formed by doping rubrene, as dopant A (organic material A), into an oligoamine compound constituting the hole injection layer 3. Note that rubrene is the same material that was used, for example, as an assist dopant for the emissive layer. No dopant B (organic material B) was doped into the hole transport layer 4.

In addition, the element of experiment number 3 was formed by doping a styryl amine compound, as dopant B, into the organic material, specifically NPB, constituting the hole transport layer 4. Note that the styryl amine compound is the same material that was used as a fluorescent material for the emissive layer 5 of this embodiment. No dopant A was doped into the hole injection layer 3.

Comparison of the measurement results shown in FIG. 3 indicates that the element for comparison having the basic structure in which neither the hole injection layer 3 nor hole transport layer 4 was doped with any dopant—just as the one of experiment number 1—had the shortest luminous half-life period, the highest drive voltage, and the lowest luminous efficacy. In addition, experiment number 2 and experiment number 3 in this order had lower drive voltage, higher luminous efficacy, and a longer luminous half-life period.

These results indicate the following. Besides a longer luminous half-life period, lower drive voltage and higher luminous efficacy can be expected when at least any one of the hole injection layer 3 and the hole transport layer 4 is doped with an organic material that is not the same organic material constituting the corresponding one of the organic layers.

In particular, in the case where the organic material used as the fluorescent material for the emissive layer 5 is doped into the hole transport layer 4 (in the case of experiment number 3), the luminous half-life period becomes significantly longer, and the luminous efficacy is enhanced significantly. In addition, even in a case where the fluorescent material doped into the hole transport layer 4 emits light, the fluorescent material that is the same one for the emissive layer 5 affects only a little the wavelength and the color of the emitted light. In sum, the use of the fluorescent material has such an advantage that the change in the color of the emitted light can be prevented. Note that the same advantageous effects can be obtained by doping, into the hole injection layer 3, the same organic material that is used as the fluorescent material for the emissive layer 5.

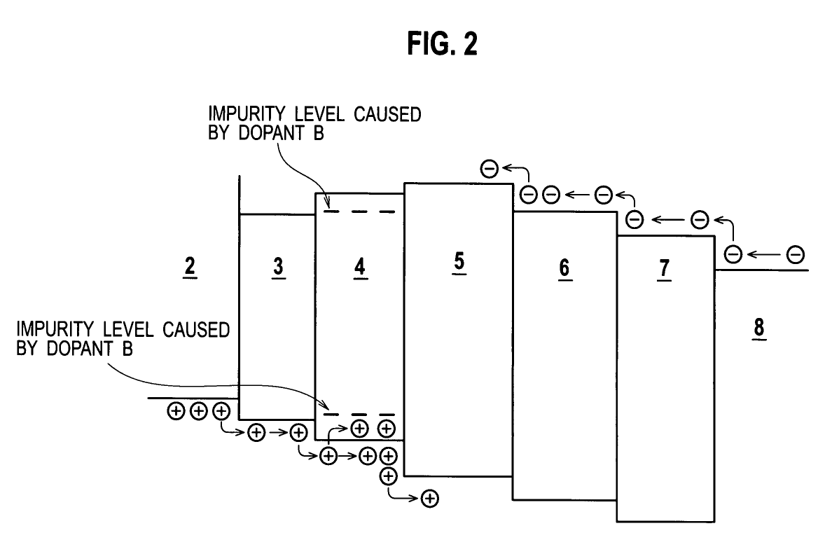

With reference to the energy diagram in FIG. 2, descriptions will be given regarding the advantageous effects of a case where at least any one of the hole injection layer 3 and the hole transport layer 4 is doped with an organic material as in the case described above. FIG. 2 shows a case where only the hole transport layer 4 is doped with the organic material B. As indicated in FIG. 2, holes are injected from the anode 2 while electrons are injected from the cathode 8. Both the holes and the electrons surmount the energy barriers existing at the interfaces between two adjacent organic layers, and move towards the emissive layer 5.

Ordinarily, the electrons have a smaller mobility due to the trap in the organic layers and the like, so that the holes reach earlier the emissive layer 5. Then, the holes accumulate one after another at the interface between the hole transport layer 4 and the emissive layer 5. With this respect, in the hole transport layer 4 of the example of FIG. 2, which is doped with a different organic material B from the organic material constituting the hole transport layer 4, an impurity level caused by dopant B appears as indicated by the dotted line in FIG. 2. The holes are trapped at this impurity level, and thus the mobility of the holes that moves within the hole transport layer 4 is lowered.

Once the mobility of the holes is lowered, the mobility of the holes becomes closer to the mobility of the electrons. Accordingly, when the amount of holes that are recombined with the electrons in the emissive layer 5 is taken into account, holes of a smaller amount accumulate, as shown in FIG. 2, at the interface between the hole transport layer 4 and the emissive layer 5. The amount of accumulated holes is decreased, so that the organic molecules in the emissive layer 5 stay shorter in a radial-cation state. As a consequence, the degradation of the organic molecules in the emissive layer 5 is suppressed, and the service life of the device becomes longer. Note that when the organic material A is doped into the hole injection layer 3, an impurity level caused by the dopant A appears in the hole injection layer 3 (not illustrated), and thus the same effects that has been described above are obtained.

As has been described thus far, when either the hole injection layer or the hole transport layer is doped with an organic material that is different from the organic material constituting the corresponding one of the organic layers, a trap for the holes can be created intentionally in either the hole injection layer or the hole transport layer. With these effects, the amount of holes accumulated at the interface between the hole transport layer and the emissive layer can be reduced, and the degradation at the interface can be suppressed. As a result, an organic EL element that has a longer service life than the conventional-type organic EL element can be obtained.

The present invention naturally includes various embodiments and the like. Accordingly, the scope of technology of the present invention can be defined only by the following claims relevant to the description thus far made.

What is claimed is:

1. An organic electroluminescence element comprising:
any one of a hole injection layer and a hole transport layer provided between an emissive layer and an anode,
wherein at least any one organic layer of the hole injection layer and the hole transport layer is doped with an organic material that is different from an organic material constituting that one organic layer.

2. The organic electroluminescence element of claim 1, wherein the doped organic material is the same fluorescent material that is used for the emissive layer.
